(19) United States
(12) Patent Application Publication
(10) Pub. No.: US 2026/0271241 A1
(43) Pub. Date: Sep. 10, 2026

(54) MEMORY COLD PLATE AND SERVER DEVICE INCLUDING THE SAME

(71) Applicants: INVENTEC (PUDONG) TECHNOLOGY CORPORATION, Shanghai (CN); INVENTEC CORPORATION, Taipei City (TW)

(72) Inventors: Chin-Cheng LEE, Taipei City (TW); Chao-Chih LIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/325,950

(22) Filed: Sep. 11, 2025

(30) Foreign Application Priority Data
Mar. 10, 2025 (CN) 202510273393.1

(51) Int. Cl. H05K 7/20

(52) U.S. Cl. CPC H05K 7/20772

(57) ABSTRACT

A memory cold plate is configured to cool at least one memory module. The memory cold plate includes a serpentine plate body, an inlet fitting, and an outlet fitting. The serpentine plate body is configured to be in thermal contact with the memory module and includes an internal flow channel configured for a coolant to flow through. The inlet fitting is disposed at one end of the serpentine plate body and in fluid communication with the internal flow channel. The outlet fitting is disposed at another end of the serpentine plate body and in fluid communication with the internal flow channel.

### CROSS-REFERENCE TO RELATED APPLICATIONS

This non-provisional application claims priority under 35 U.S.C. § 119(a) on Patent Application No(s). 202510273393.1 filed in China, on Mar. 10, 2025, the entire contents of which are hereby incorporated by reference.

### BACKGROUND OF THE INVENTION

### Technical Field of the Invention

This invention relates to a memory cold plate and a server device including the same, especially to a memory cold plate configured with a serpentine plate body and a server device including the same.

### Description of the Related Art

Conventional servers primarily adopt air-cooling for heat dissipation. However, as transistor density in various chips continues to increase, the heat generated by these chips can no longer be effectively dissipated solely through fan-based air cooling. Moreover, with the advancement of artificial intelligence (AI) technology, market demand for computing power is continually rising, further intensifying the need for high-efficiency thermal management. As a result, liquid cooling has gradually become the most economical choice for data center heat dissipation.

In conventional servers, central processing units (CPUs) and dual in-line memory modules (DIMMs) are among the major heat-generating components. Several commonly used DIMM cold plates for cooling these dual in-line memory modules require both of their fluid inlets and outlets to be welded to manifolds in order to achieve coolant distribution and collection.

Therefore, how to simplify the structural design of DIMM cold plates to reduce manufacturing costs and improve cooling performance has become a key research direction in server cooling technology.

### SUMMARY OF THE INVENTION

The invention provides a memory cold plate and a server device including the same, thereby simplifying the structural design of the DIMM cold plate to reduce manufacturing costs and improve heat dissipation performance.

One embodiment of the invention provides a memory cold plate configured to cool at least one memory module. The memory cold plate includes a serpentine plate body, an inlet fitting, and an outlet fitting. The serpentine plate body is configured to be in thermal contact with the memory module and includes an internal flow channel, and the internal flow channel is configured for a coolant to flow through. The inlet fitting is disposed at one end of the serpentine plate body and in fluid communication with the internal flow channel. The outlet fitting is disposed at another end of the serpentine plate body and in fluid communication with the internal flow channel.

One embodiment of the invention provides a server device including a motherboard, at least one memory module, and a memory cold plate. The memory module is disposed on the motherboard. The memory cold plate includes a serpentine plate body, an inlet fitting, and an outlet fitting. The serpentine plate body is in thermal contact with the memory module and includes an internal flow channel, and the internal flow channel is configured for a coolant to flow through. The inlet fitting is disposed at one end of the serpentine plate body and in fluid communication with the internal flow channel. The outlet fitting is disposed at another end of the serpentine plate body and in fluid communication with the internal flow channel.

According to the memory cold plate and the server device including the same as described above, the memory cold plate is designed in a serpentine shape to form a plurality of heat dissipation accommodating spaces for housing and being in thermal contact with a plurality of memory modules, thereby enabling efficient heat dissipation for the memory modules through a single serpentine flow path. In addition, the serpentine plate body of the memory cold plate is configured with a fluid inlet and a fluid outlet only at its head and tail ends, thereby reducing the number of connections (or welds) between pipes and plates in the cooling system and simplifying the overall structural design.

### BRIEF DESCRIPTION OF THE DRAWINGS

The invention will become more fully understood from the detailed description given hereinbelow and the accompanying drawings which are given by way of illustration only and thus are not limitative of The invention and wherein:

FIG. 1 is a partial perspective view of a server device in accordance with one embodiment of the invention;

FIG. 2 is an exploded view of the server device shown in FIG. 1; and

FIG. 3 is a top view of the server device shown in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

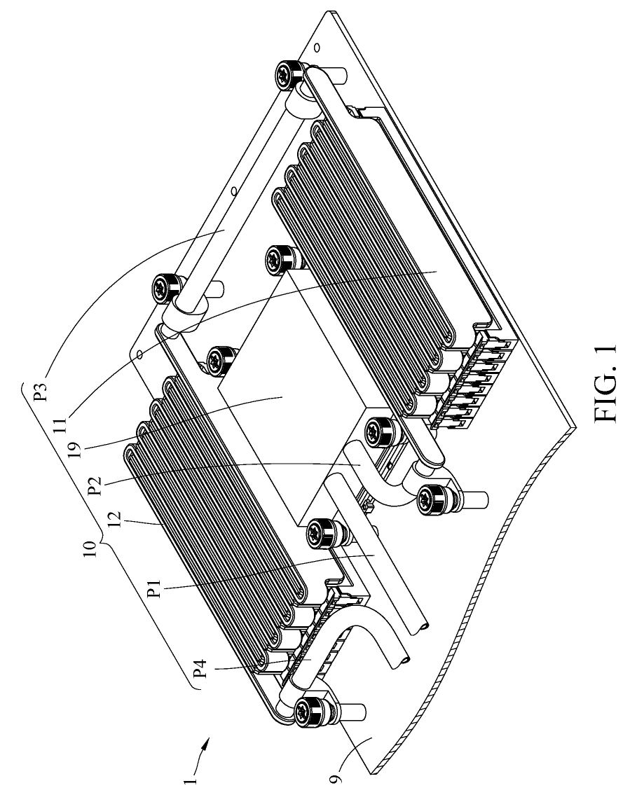

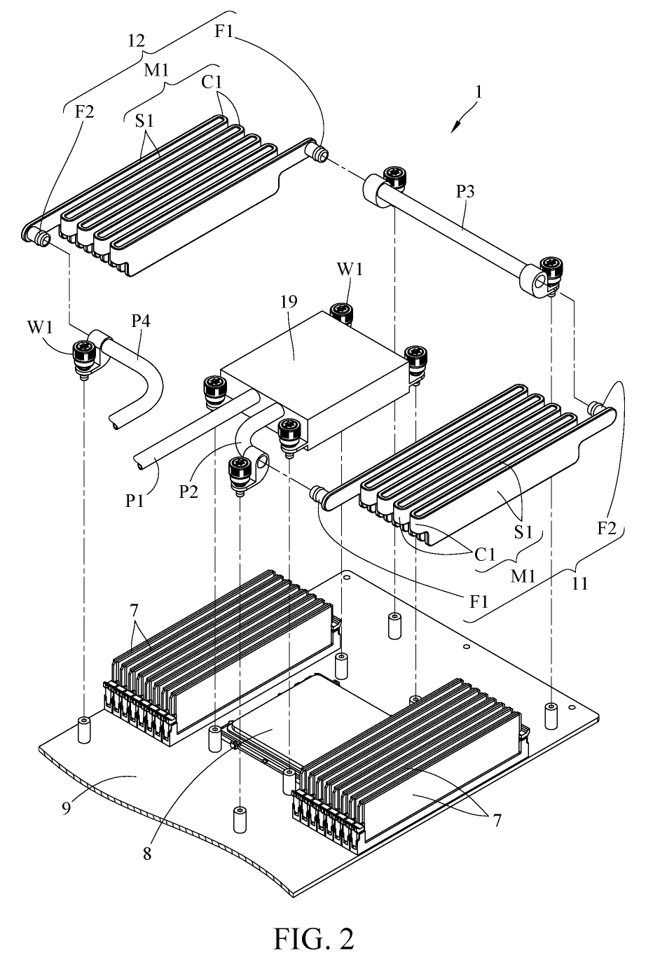

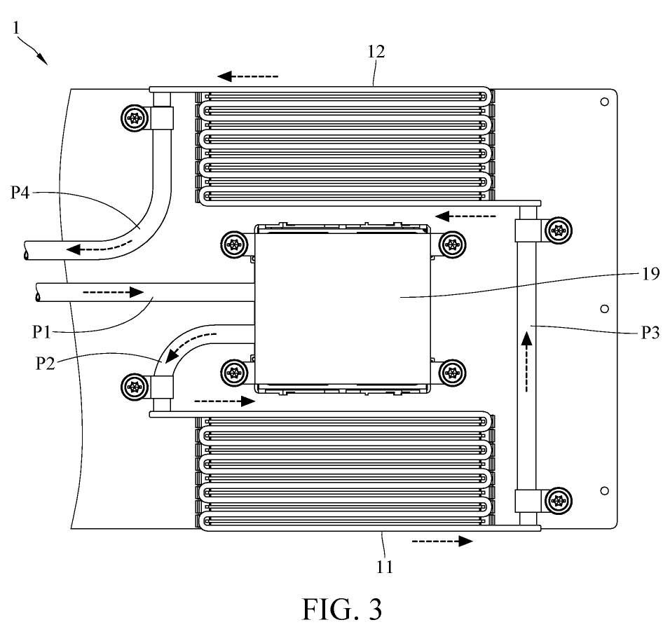

Referring to FIGS. 1 to 3, FIG. 1 is a partial perspective view of a server device in accordance with one embodiment of the invention, FIG. 2 is an exploded view of the server device shown in FIGS. 1, and 3 is a top view of the server device shown in FIG. 1.

In this embodiment, a server device 1 is provided. The server device 1 includes a motherboard 9, a central processing unit 8, a plurality of memory modules 7, and a liquid cooling heat dissipation assembly 10. The central processing unit 8 and the memory modules 7 are disposed on the motherboard 9. The liquid cooling heat dissipation assembly 10 is configured to cool the central processing unit 8 and the memory modules 7. In addition, the memory modules 7 are, for example, Dual In-line Memory Modules (DIMMs).

The liquid cooling heat dissipation assembly 10 includes a processor cold plate 19, a first memory cold plate 11, a second memory cold plate 12, and a plurality of connecting flow pipes P1, P2, P3, and P4.

The processor cold plate 19 is in thermal contact with the central processing unit 8 and configured for a coolant to flow through, and the processor cold plate 19 is in fluid communication with a coolant distribution unit (CDU) via the connecting flow pipe P1. By directing the coolant from the coolant distribution unit to the processor cold plate 19, heat dissipation for the central processing unit 8 can be achieved. The coolant distribution unit may include a heat exchanger for cooling the coolant.

The first memory cold plate 11 and the second memory cold plate 12 are respectively in thermal contact with the memory modules 7 and configured for the coolant to flow through. Specifically, each of the first memory cold plate 11 and the second memory cold plate 12 includes a serpentine plate body M1, an inlet fitting F1, and an outlet fitting F2. The serpentine plate body M1 includes an internal flow channel (not shown in figures), and the internal flow channel is configured for the coolant to flow through. The inlet fitting F1 is disposed at one end of the serpentine plate body M1 and in fluid communication with the internal flow channel, and the outlet fitting F2 is disposed at another end of the serpentine plate body M1 and in fluid communication with the internal flow channel. Additionally, the serpentine plate body M1 includes a plurality of flat plate sections S1 and a plurality of bent sections C1. The flat plate sections S1 are arranged side by side, and the bent sections C1 are respectively connected to any adjacent two of the flat plate sections S1, such that the flat plate sections S1 and the bent sections C1 are alternately connected in series to jointly form the serpentine plate body M1. The overall shape of the serpentine plate body M1 is, for example, similar to the shape of a sine wave, and the internal flow channel of the serpentine plate body M1 is an enclosed flow channel.

As shown in FIG. 1 and FIG. 3, in each of the memory cold plates 11 and 12, the flat plate sections S1 are arranged parallel to and staggered with the memory modules 7 corresponding thereto, such that the memory modules 7 are respectively disposed within heat dissipation accommodating spaces (not indicated by reference numerals) formed between each pair of adjacent flat plate sections S1. Moreover, each of the memory modules 7 is in thermal contact with two adjacent flat plate sections S1 on its opposing sidewalls. Accordingly, the heat generated by the memory modules 7 is conducted to the flat plate sections S1 of the serpentine plate body M1, and then carried away by the coolant flowing through the memory cold plates 11 and 12, thereby enabling effective heat dissipation for the memory modules 7.

In this embodiment, a width of each of the flat plate sections S1 is smaller than or equal to a width of each of the two memory modules 7 adjacent thereto. A height of each of the flat plate sections S1 is equal to a height of each of the memory modules 7; that is, after the memory modules 7 are installed in the sockets, an upper edge of the memory modules 7 is aligned with an upper edge of the flat plate sections S1 along the same horizontal line.

By designing the memory cold plates 11 and 12 in a serpentine shape with multiple bends, a plurality of heat dissipation accommodating spaces are formed to accommodate and be in thermal contact with the memory modules 7, thereby enabling effective heat dissipation for the memory modules 7 through a single serpentine flow channel (i.e., the internal flow channel of the serpentine plate body M1). In addition, the serpentine plate body M1 of each of the memory cold plates 11 and 12 is configured with a fluid inlet and a fluid outlet only at its head and tail ends (corresponding to the locations where the inlet fitting F1 and the outlet fitting F2 are provided), thereby reducing the number of connections (or welds) between the pipes and plates in the cooling system, simplifying the overall structural design, lowering manufacturing costs, and enhancing heat dissipation performance.

The inlet fitting F1 of the first memory cold plate 11 is connected to the processor cold plate 19 via the connecting flow pipe P2, the outlet fitting F2 of the first memory cold plate 11 is connected to the inlet fitting F1 of the second memory cold plate 12 via the connecting flow pipe P3, and the outlet fitting F2 of the second memory cold plate 12 is connected to the coolant distribution unit via the connecting flow pipe P4, thereby directing the coolant from the second memory cold plate 12 to the coolant distribution unit. Additionally, the heat exchanger of the coolant distribution unit is configured to cool the coolant.

Through the above configuration, as shown in FIG. 3, a series-connected cooling loop is formed among the processor cold plate 19, the first memory cold plate 11, and the second memory cold plate 12, allowing the coolant to sequentially flow from the coolant distribution unit through the processor cold plate 19, the first memory cold plate 11, and the second memory cold plate 12, and then return to the coolant distribution unit, thereby completing a primary side cooling cycle and enabling effective heat dissipation for the central processing unit 8 and the memory modules 7. Furthermore, the coolant, for example, flows at high speed through the cooling loop to achieve rapid heat removal.

In this embodiment, the server device of the invention can be used for artificial intelligence (AI) computing and edge computing, and may also serve as a 5G server, cloud server, or vehicle-to-everything (V2X) server.

The invention is not limited to the aforementioned flow direction of the coolant. In other configurations, the coolant may, for example, sequentially flow from the coolant distribution unit through the second memory cold plate, the first memory cold plate, and the processor cold plate, and then return to the coolant distribution unit.

In some configurations, the coolant distribution unit additionally completes a secondary side cooling circulation loop through a building’s cooling tower and the ambient environment, thereby ultimately releasing heat into the environment. By utilizing liquid cooling technology, the air-conditioning load of the data center can be effectively reduced, further optimizing power usage effectiveness (PUE).

In some configurations, the liquid cooling heat dissipation assembly further includes a plurality of thermal pads, each of the thermal pads is disposed between the flat plate section and the memory module that are adjacent to each other and is thermally coupled to both, thereby enabling the flat plate sections to be in thermal contact with the memory modules via the thermal pads. The thermal pads may, for example, be arranged only on the chip modules of the memory modules 7 or over the entire memory modules 7. In this manner, the heat generated by the memory modules is conducted through the thermal pads to the flat plate sections of the memory cold plate, and then carried away by the coolant flowing through the memory cold plate, thereby achieving effective heat dissipation for the memory modules. In addition to conducting heat from the memory modules 7 to the flat plate sections S1, the thermal pads also serve to protect the chip modules of the memory modules 7 during the removal or installation of the flat plate sections S1 or the memory modules 7, preventing the chip modules from being scratched by the flat plate sections S1, which are mostly made of metal.

In this embodiment, the number of memory cold plates is two, but the invention is not limited thereto. In other embodiments, the number of memory cold plates may be, for example, one or more than two, depending on the number and distribution of memory modules to be cooled.

In this embodiment, the cooling flow paths of the processor cold plate 19, the first memory cold plate 11, and the second memory cold plate 12 are connected in series, but the invention is not limited thereto. In other embodiments, the cooling flow path through the memory cold plate is independent of the cooling flow path through the processor cold plate. In other words, the inlet fitting and the outlet fitting of the memory cold plate are respectively connected directly to the coolant distribution unit via connecting flow pipes, without being connected in series with the processor cold plate. As such, the cooling flow path through the memory cold plate and the cooling flow path through the processor cold plate may be, for example, in a parallel arrangement.

In this embodiment, the processor cold plate 19 and the memory cold plates 11 and 12 are secured directly or indirectly to the motherboard via screws W1, but the invention is not limited thereto. For example, in other embodiments, the memory cold plate may be fastened to a frame mounted on the motherboard, such that the memory cold plate is indirectly secured to the motherboard via the frame.

According to the memory cold plate and the server device including the same described above, by designing the memory cold plate in a serpentine shape to form multiple heat dissipation accommodating spaces for housing and thermally contacting multiple memory modules, effective heat dissipation for the memory modules can be achieved through a single serpentine flow path. Furthermore, the serpentine plate body of the memory cold plate is configured with a fluid inlet and a fluid outlet only at its head and tail ends, thereby reducing the number of connections (or welds) between pipes and plates in the cooling system, which simplifies the overall structural design, reduces manufacturing costs, and enhances heat dissipation performance.

In addition, to maximize power usage efficiency, while the central processing unit dissipates heat through the processor cold plate, the memory modules on both sides of the central processing unit also dissipate heat using a liquid cooling approach, either through an independent cooling loop or through memory cold plates connected in series to the cooling loop of the processor cold plate. This design reduces the load on the air conditioning system of the data center, thereby improving overall power usage efficiency.

It will be apparent to those skilled in the art that various modifications and variations can be made to the invention. It is intended that the specification and examples be considered as exemplary embodiments only, with a scope of the invention being indicated by the following claims and their equivalents.

What is claimed is:

1. A memory cold plate configured to cool at least one memory module, and the memory cold plate comprising:
a serpentine plate body comprising an internal flow channel, the internal flow channel configured for a coolant to flow through, and the serpentine plate body configured to be in thermal contact with the at least one memory module;
an inlet fitting disposed at one end of the serpentine plate body and in fluid communication with the internal flow channel; and
an outlet fitting disposed at another end of the serpentine plate body and in fluid communication with the internal flow channel.

2. The memory cold plate according to claim 1, wherein the serpentine plate body comprises a plurality of flat plate sections and a plurality of bent sections, the plurality of flat plate sections are arranged side by side, and the plurality of bent sections are respectively connected to any adjacent two of the plurality of flat plate sections, such that the plurality of flat plate sections and the plurality of bent sections are alternately connected in series to jointly form the serpentine plate body, and
wherein the plurality of flat plate sections are configured to be arranged parallel to and staggered with the at least one memory module, and the at least one memory module is respectively disposed within a heat dissipation accommodating space formed between any adjacent two of the plurality of flat plate sections.

3. The memory cold plate according to claim 2, wherein the plurality of flat plate sections are configured to be in thermal contact with the at least one memory module via a thermal pad.

4. The memory cold plate according to claim 1, wherein the inlet fitting is configured to be connected to a coolant distribution unit and/or a processor cold plate via a connecting flow pipe, and the outlet fitting is configured to be connected to the coolant distribution unit via another connecting flow pipe.

5. A server device comprising:
a motherboard;
at least one memory module disposed on the motherboard; and
a memory cold plate comprising:
a serpentine plate body comprising an internal flow channel, the internal flow channel configured for a coolant to flow through, and the serpentine plate body in thermal contact with the at least one memory module;
an inlet fitting disposed at one end of the serpentine plate body and in fluid communication with the internal flow channel; and
an outlet fitting disposed at another end of the serpentine plate body and in fluid communication with the internal flow channel.

6. The server device according to claim 5, wherein the serpentine plate body comprising a plurality of flat plate sections and a plurality of bent sections, the plurality of flat plate sections are arranged side by side, and the plurality of bent sections are respectively connected to any adjacent two of the plurality of flat plate sections, such that the plurality of flat plate sections and the plurality of bent sections are alternately connected in series to jointly form the serpentine plate body, and
wherein the plurality of flat plate sections are arranged parallel to and staggered with the at least one memory module, and the at least one memory module is respectively disposed within a heat dissipation accommodating space formed between any adjacent two of the plurality of flat plate sections.

7. The server device according to claim 6, further comprising a liquid cooling heat dissipation assembly, wherein the liquid cooling heat dissipation assembly comprises the memory cold plate and at least one thermal pad, the at least one thermal pad is disposed between the plurality of flat plate sections and the at least one memory module, and the plurality of flat plate sections are in thermal contact with the at least one memory module via the at least one thermal pad.

8. The server device according to claim 7, further comprising a central processing unit disposed on the motherboard, wherein the liquid cooling heat dissipation assembly further comprises a processor cold plate and a plurality of connecting flow pipes, the inlet fitting is connected to the processor cold plate and/or a coolant distribution unit via one of the plurality of connecting flow pipes, and the outlet fitting is connected to the coolant distribution unit via another of the plurality of connecting flow pipes.
